(19) United States
(12) Patent Application Publication
(10) Pub. No.: US 2025/0386581 A1
(43) Pub. Date: Dec. 18, 2025

(54) MEMORY AND MANUFACTURING METHOD THEREOF

(71) Applicant: SwaySure Technology Co., Ltd., Shenzhen (CN)

(72) Inventor: Junhui LI, Shenzhen (CN)

(21) Appl. No.: 19/211,616

(22) Filed: May 19, 2025

(30) Foreign Application Priority Data
Jun. 17, 2024 (CN) 202410782859.6
Jun. 17, 2024 (CN) 202421387122.6

(51) Int. Cl. H10D 64/27; G11C 5/06; G11C 11/4096; H10B 12/00

(52) U.S. Cl. CPC H10D 64/514; G11C 5/063; G11C 11/4096; H10B 12/01

(57) ABSTRACT

A memory includes a substrate and at least one storage layer. The storage layer is formed on the substrate, and the storage layer includes storage units. Each storage unit includes: a read transistor and a write transistor, the read transistor includes a first gate electrode, a first semiconductor layer, and a first gate insulating layer formed between the first gate electrode and the first semiconductor layer. The first gate electrode includes a gate bottom wall and a gate sidewall. The gate sidewall and the gate bottom wall enclose to form a gate groove. The write transistor includes a second gate electrode, a second semiconductor layer, and a second gate insulating layer formed between the second gate electrode and the second semiconductor layer. A part of the second semiconductor layer is embedded in the gate groove and is in contact with at least a part of the gate groove.

### CROSS-REFERENCE TO RELATED APPLICATIONS

This application claims priority to Chinese Patent Application No. 202410782859.6, filed on Jun. 17, 2024, and Chinese Patent Application No. 202421387122.6, filed on Jun. 17, 2024, the entire disclosures of which are hereby incorporated herein by reference.

### TECHNICAL FIELD

The present disclosure belongs to the field of semiconductor technology and specifically relates to a memory and a manufacturing method thereof.

### BACKGROUND

With the miniaturization of technology nodes, the storage units of Dynamic Random Access Memory (DRAM) are gradually transitioning from 1 transistor and 1 capacitor (1T1C) structure to the planar 2T0C structure (that is, a structure with 2 horizontally arranged transistors and no capacitor). However, this design results in a still relatively low storage density of DRAM and a rather complex manufacturing process.

### SUMMARY

There are provided a memory and a manufacturing method thereof according to embodiments of the present disclosure. The technical solution is as below:

A first aspect of the present disclosure provides a memory device, which includes a substrate and at least one storage layer formed on the substrate, the storage layer includes a storage unit, and the storage unit includes:
a read transistor, including a first gate electrode, a first semiconductor layer at least horizontally surrounding an outer peripheral side of the first gate electrode, and a first gate insulating layer formed between the first gate electrode and the first semiconductor layer,
the first gate electrode includes a gate bottom wall and a gate sidewall, and the gate sidewall horizontally surrounds the gate bottom wall and extends in a direction away from the substrate, and the gate sidewall and the gate bottom wall enclose to form a gate groove; and
a write transistor, including a second gate electrode, a second semiconductor layer at least horizontally surrounding an outer peripheral side of the second gate electrode, and a second gate insulating layer formed between the second gate electrode and the second semiconductor layer;
a part of the second semiconductor layer is embedded in the gate groove and is in contact with at least a part of the gate groove.

A second aspect of the present disclosure provides a method for manufacturing a memory, including:
providing a substrate; and
forming at least one storage layer on the substrate,
wherein the forming the at least one storage layer includes:
forming a read transistor on the substrate, wherein the read transistor includes a first gate electrode, a first semiconductor layer at least horizontally surrounding an outer peripheral side of the first gate electrode, and a first gate insulating layer formed between the first gate electrode and the first semiconductor layer, wherein the first gate electrode includes a gate bottom wall and a gate sidewall, and wherein the gate sidewall horizontally surrounds the gate bottom wall and extends in a direction away from the substrate, and the gate sidewall and the gate bottom wall enclose to form a gate groove; and
forming a write transistor at the gate groove to form a storage unit, wherein the write transistor includes a second gate electrode, a second semiconductor layer at least horizontally surrounding an outer peripheral side of the second gate electrode, and a second gate insulating layer formed between the second gate electrode and the second semiconductor layer; and wherein a part of the second semiconductor layer is embedded at the gate groove and is in contact with at least part of the gate groove.

### BRIEF DESCRIPTION OF THE DRAWINGS

The accompanying drawings herein are incorporated into the specification and constitute a part of the specification, showing the embodiments in accordance with the present disclosure, and are used together with the specification to explain the principles of the present disclosure. Obviously, the accompanying drawings described below are only some embodiments of the present disclosure. For those skilled in the art, other accompanying drawings can be obtained according to these accompanying drawings without creative efforts.

FIGS. 1 to 6 respectively show the structural schematic diagrams of the memory under different embodiments of the present disclosure.

FIGS. 7 to 24 respectively show the structural schematic diagrams after different steps are executed in the method for manufacturing the memory of the present disclosure.

### DETAILED DESCRIPTION OF THE EMBODIMENTS

The exemplary embodiments will now be described more comprehensively with reference to the accompanying drawings. However, the exemplary embodiments can be implemented in various forms and should not be construed as being limited to the examples set forth herein; instead, these embodiments are provided so that this application will be more comprehensive and complete, and the concept of the exemplary embodiments will be fully conveyed to those skilled in the art.

In addition, the described features, structures, or characteristics can be combined in any suitable manner in one or more embodiments. In the following description, numerous specific details are provided to give a thorough understanding of the embodiments of this application. However, those skilled in the art will recognize that the technical solutions of this application can be practiced without one or more of these specific details, or other methods, components, devices, steps, etc. can be employed. In other cases, well-known methods, devices, implementations, or operations are not shown or described in detail to avoid obscuring various aspects of this application.

The present application will be further described in detail below in combination with the accompanying drawings and specific embodiments. It should be noted here that the technical features involved in the various embodiments of this application described below can be combined with each other as long as they do not conflict with one another. The embodiments described below with reference to the accompanying drawings are exemplary and are intended to explain this application, but should not be construed as limiting this application.

The embodiments of the present disclosure provide a memory, which may include a substrate and at least one storage layer.

The memory according to the embodiments of the present disclosure will be described in detail below with reference to the accompanying drawings.

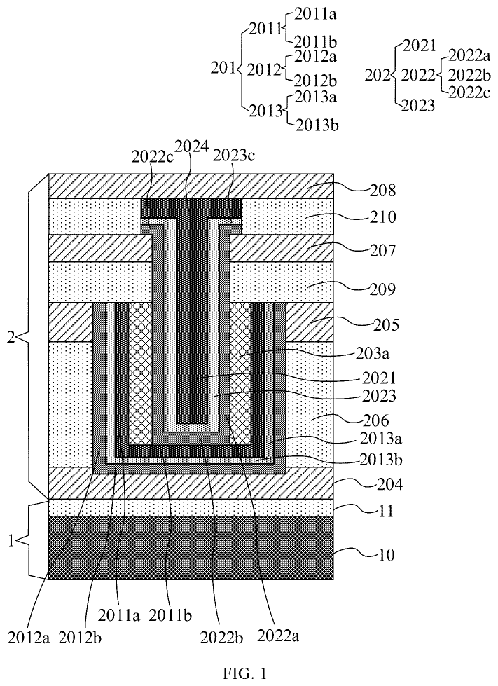

Referring to FIG. 1, the substrate 1 may be a stacked structure. For example, the substrate 1 may include a semiconductor substrate layer 10 and an insulating substrate layer 11 formed on the semiconductor substrate layer 10. The semiconductor substrate layer 10 may include semiconductor materials such as single crystal silicon, but is not limited thereto, and may also include semiconductor materials such as germanium (Ge). The insulating substrate layer 11 may include insulating materials such as silicon dioxide, but is not limited thereto. The insulating substrate layer 11 may also be made of other materials with insulating properties, depending on the actual situation.

It should be understood that the substrate 1 of this embodiment is not limited to the stacked structure shown in FIG. 1, and may also be a single-layer structure. For example, the substrate 1 may be a single-layer structure made of semiconductor materials, or a single-layer structure made of insulating materials, etc., depending on the specific situation.

Referring to FIG. 1, the storage layer 2 may be formed on the substrate 1. For example, when the substrate 1 is a stacked structure including the semiconductor substrate layer 10 and the insulating substrate layer 11, the storage layer 2 may be formed on the top surface of the insulating substrate layer 11 away from the semiconductor substrate layer 10.

Continuing to refer to FIG. 1, the storage layer 2 may include storage units. The storage unit may include two transistors, for example, a read transistor 201 and a write transistor 202. Both the read transistor 201 and the write transistor 202 may be of the Channel-All-Around (CAA) type. Specifically, the read transistor 201 may include a first gate electrode 2011, a first semiconductor layer 2012 that at least horizontally surrounds the outer peripheral side of the first gate electrode 2011, and a first gate insulating layer 2013 formed between the first gate electrode 2011 and the first semiconductor layer 2012. The write transistor 202 may include a second gate electrode 2021, a second semiconductor layer 2022 that at least horizontally surrounds the outer peripheral side of the second gate electrode 2021, and a second gate insulating layer 2023 formed between the second gate electrode 2021 and the second semiconductor layer 2022.

Exemplarily, the first semiconductor layer 2012 and the second semiconductor layer 2022 may be made of the same the materials. For example, both the first semiconductor layer 2012 and the second semiconductor layer 2022 may be made of indium gallium zinc oxide (IGZO). Since the semiconductor layers are made of IGZO, there is no need to dope the first semiconductor layer 2012 and the second semiconductor layer 2022 to form the source and drain regions, and the leakage current is small, thus increasing the storage time and improving the storage performance, but it is not limited thereto. The first semiconductor layer 2012 and the second semiconductor layer 2022 may also be made of other semiconductor materials such as indium aluminum zinc oxide (IAZO), as long as the storage time and storage performance of the transistors can be ensured. In addition, the first semiconductor layer 2012 and the second semiconductor layer 2022 may also be made of different materials, depending on the specific situation.

Exemplarily, the first gate electrode 2011 and the second gate electrode 2021 may be made of the same materials. For example, both the first gate electrode 2011 and the second gate electrode 2021 may be made of conductive materials such as tungsten metal, but are not limited thereto, and other materials with good electrical conductivity may also be used according to specific requirements. In addition, the first gate electrode 2011 and the second gate electrode 2021 may also be made of different materials, depending on the specific situation.

Exemplarily, the first gate insulating layer 2013 and the second gate insulating layer 2023 may be made of the same materials. For example, both the first gate insulating layer 2013 and the second gate insulating layer 2023 may be made of insulating materials such as silicon dioxide, but are not limited thereto, and other insulating materials may also be used. In addition, the first gate insulating layer 2013 and the second gate insulating layer 2023 may also made of different materials, depending on the specific situation.

In this embodiment, the first gate electrode 2011 of the read transistor 201 may be designed in a groove shape. Specifically, in the read transistor 201, the first gate electrode 2011 may include a gate sidewall 2011a and a gate bottom wall 2011b. The gate sidewall 2011a horizontally surrounds the gate bottom wall 2011b and extends in a direction away from the substrate 1. The gate sidewall 2011a and the gate bottom wall 2011b enclose to form a gate groove. A part of the write transistor 202 may be vertically nested in the read transistor 201. Specifically, a part of the second semiconductor layer 2022 in the write transistor 202 is embedded in the gate groove of the first gate electrode 2011 and is in contact with at least part of the gate groove in the first gate electrode 2011, that is, it may be in contact with at least one of the gate sidewall 2011a and the gate bottom wall 2011b.

In the present disclosure, since the CAA-type write transistor 201 in the storage unit is partially and vertically nested inside the CAA-type read transistor 201, compared with the planar 2T0C storage unit, while ensuring the storage density of the storage unit, not only can the horizontal area occupied by the storage unit be reduced, but also the vertical height of the storage unit can be decreased. That is, the entire volume of the storage unit can be reduced, namely, the space occupied by the storage unit can be minimized. In this way, more storage units can be arranged in a memory of a certain volume, thereby improving the storage density of the memory.

In addition, in the present disclosure, since the semiconductor layer of the write transistor 202 is located in the gate groove of the gate electrode of the read transistor 201, it can directly contact the gate electrode of the read transistor 201, so as to realize the connection of the write transistor 202 and the read transistor 201. Compared with the planar 2T0C storage unit, there is no need to design additional connection patterns to connect the write transistor 202 and the read transistor 201 together. Thus, the requirements for the photolithography process during the manufacturing process can be reduced, and then the product yield can be improved and the production cost can be lowered.

It should be understood that the position where the gate groove of the first gate electrode 2011 is in contact with the second semiconductor layer 2022 can be regarded as the storage node of the storage unit. For example, the position where the gate bottom wall 2011b is in contact with the second semiconductor layer 2022 in FIG. 1 can be regarded as the storage node.

In some embodiments, referring to FIG. 1, in the write transistor 202, each of the second semiconductor layer 2022, the second gate electrode 2021, and the second gate insulating layer 2023 may has an embedding portion and an extension portion. The embedding portion may be the part of the second semiconductor layer 2022, the second gate electrode 2021, and the second gate insulating layer 2023 that is embedded in the gate groove. It should be understood that the embedding portion of the second semiconductor layer 2022 is in contact with at least part of the gate groove to realize the connection between the write transistor 202 and the read transistor 201. The extension portion may be the part of the second semiconductor layer 2022, the second gate electrode 2021, and the second gate insulating layer 2023 on the side of the embedding portion away from the substrate 1, and this extension portion protrudes in a direction away from the substrate 1 relative to the read transistor 201.

In this embodiment, since the bottoms of the second semiconductor layer 2022, the second gate electrode 2021, and the second gate insulating layer 2023 in the write transistor 202 are all embedded in the gate groove of the first gate electrode 2011, the vertical height of the storage unit can be further reduced while ensuring the storage density.

Exemplarily, referring to FIG. 1, the embedding portion of the second semiconductor layer 2022 may include a second semiconductor sidewall 2022a and a second semiconductor bottom wall 2022b. The second semiconductor sidewall 2022a horizontally surrounds the second semiconductor bottom wall 2022b and extends in the direction away from the substrate 1. The second semiconductor sidewall 2022a and the second semiconductor bottom wall 2022b enclose to form a second semiconductor groove, and the embedding portion of the second gate electrode 2021 and the embedding portion of the second gate insulating layer 2023 are located in the second semiconductor groove.

Referring to FIG. 1, the bottom surface of the second semiconductor bottom wall 2022b and the bottom surface of the second semiconductor sidewall 2022a are both in contact with the gate bottom wall 2011b, such a design can ensure the contact area between the second semiconductor layer 2022 and the first gate electrode 2011, and the process difficulty during manufacturing is also low.

In some embodiments, referring to FIG. 1, the storage unit may also include an insulating dielectric sidewall 203a. The insulating dielectric sidewall 203a is embedded in the gate groove and horizontally surrounds the outer peripheral side of the embedding portion of the second semiconductor layer 2022. The outer peripheral surface of the embedding portion of the second semiconductor layer 2022 is insulated from the gate sidewall 2011a through the insulating dielectric sidewall 203a, and the bottom surface of the embedding portion of the second semiconductor layer 2022 is in contact with the gate bottom wall 2011b, such a design can realize the connection between the write transistor 202 and the read transistor 201, and can make the embedding portion of the second semiconductor layer 2022 to be a part of the channel of the write transistor 202. When a channel length of the write transistor 202 meets the requirements, the height of the second semiconductor layer 2022 protruding from the read transistor 201 can be reduced, that is, the height of the extension portion of the second semiconductor layer 2022 can be reduced, thereby further reducing a vertical height of the storage unit.

In some embodiments, the insulating dielectric sidewall 203a may include a low dielectric material portion. The low dielectric material portion is made of a material with a dielectric constant lower than 3.0, and this low dielectric material portion can horizontally surround the outer peripheral side of the embedding portion of the second semiconductor layer 2022 to reduce the parasitic capacitance generated between the second semiconductor layer 2022 and the first gate electrode 2011.

In other embodiments, the insulating dielectric sidewall 203a may also include a silicon dioxide material layer. The silicon dioxide material layer horizontally surrounds the outer peripheral side of the embedding portion of the second semiconductor layer 2022 to insulate the embedding portion of the second semiconductor layer 2022 from the gate sidewall 2011a of the first gate electrode 2011, and the material cost can be reduced.

In another embodiments, the insulating dielectric sidewall 203a may include a stacked structure in which the low dielectric material portion and the silicon dioxide material layer are nested together, so that the parasitic capacitance can be reduced while reducing the material cost.

In some embodiments of the present disclosure, referring to FIG. 1, in addition to the storage unit, the storage layer 2 may also include a first signal line 204 and a second signal line 205. Combining FIGS. 1 to 3, the first signal line 204 is formed on the substrate 1. The first signal line 204 extends in the first horizontal direction X and is in contact with the bottom surface of the first semiconductor layer 2012 and/or the bottom region of the outer peripheral surface of the first semiconductor layer 2012. The second signal line 205 is formed on the side of the first signal line 204 away from the substrate 1. A first interlayer insulating layer 206 is formed between the layer where the second signal line 205 is located and the layer where the first signal line 204 is located. The second signal line 205 extends in the second horizontal direction Y intersecting with the first horizontal direction X. The second signal line 205 and the first interlayer insulating layer 206 horizontally surround the outer peripheral side of the first semiconductor layer 2012, and the second signal line 205 is in contact with the top region of the outer peripheral surface of the first semiconductor layer 2012. One of the first signal line 204 and the second signal line 205 is a read bit line, and the other is a read word line.

For example, the first signal line 204 and the second signal line 205 may be made of the same materials. For example, both may be made of conductive materials such as tungsten metal, but are not limited thereto, and other materials with electrical conductivity may also be used. In addition, the first signal line 204 and the second signal line 205 may be signal lines made of a single material, but are not limited thereto, and may also be composite signal lines stacked by a plurality of materials, depending on the specific situation. The first interlayer insulating layer 206 may be made of materials such as silicon dioxide, but is not limited thereto, and other insulating materials may also be used, depending on the specific situation.

Referring to FIG. 1, the first semiconductor layer 2012 of the read transistor 201 is formed on the side of the first signal line 204 away from the substrate 1, and both the first semiconductor layer 2012 and the first gate insulating layer 2013 of the read transistor 201 may be designed in a groove shape. In this embodiment, the first gate insulating layer 2013 and the first gate electrode 2011 can be designed and cooperate with each other according to the shape of the first semiconductor layer 2012, so as to simplify the process steps, reduce the process cost, and ensure the channel length of the read transistor 201.

In detail, referring to FIG. 1, the first semiconductor layer 2012 may include a first semiconductor sidewall 2012a and a first semiconductor bottom wall 2012b. The first semiconductor sidewall 2012a horizontally surrounds the first semiconductor bottom wall 2012b and extends in the direction away from the substrate 1. The first semiconductor sidewall 2012a and the first semiconductor bottom wall 2012b enclose to form a first semiconductor groove, the bottom surfaces of both the first semiconductor sidewall 2012a and the first semiconductor bottom wall 2012b are in contact with the first signal line 204.

Referring to FIG. 1, the first gate insulating layer 2013 includes a first gate insulating sidewall 2013a and a first gate insulating bottom wall 2013b. The first gate insulating bottom wall 2013b is located in the first semiconductor groove and is in contact with the top surface of the first semiconductor bottom wall 2012b. The first gate insulating sidewall 2013a is at least located in the first semiconductor groove and horizontally surrounds the first gate insulating bottom wall 2013b. The first gate insulating sidewall 2013a extends in a direction away from the substrate 1 and encloses to form a first gate insulating groove with the first gate insulating bottom wall 2013b, and the outer peripheral surface of the first gate insulating sidewall 2013a is in contact with the inner peripheral surface of the first semiconductor sidewall 2012a. The gate bottom wall 2011b is located within the first gate insulating groove and is in contact with the top surface of the first gate insulating bottom wall 2013b. The gate sidewall 2011a is at least located within the first gate insulating groove, and the outer peripheral surface of the gate sidewall 2011a is in contact with the inner peripheral surface of the first gate insulating sidewall 2013a.

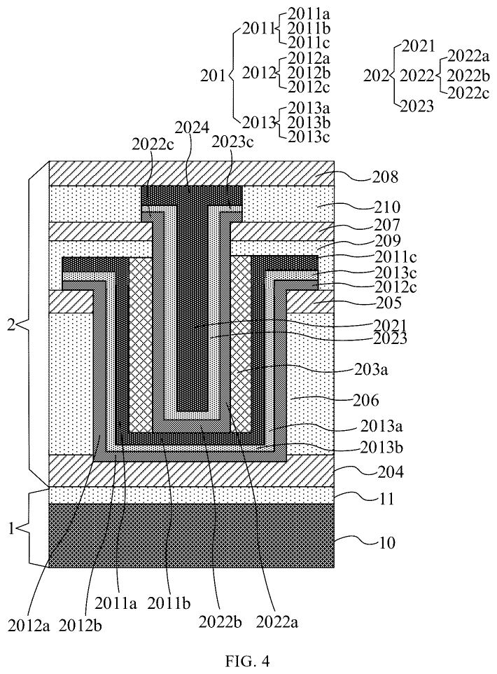

In some embodiments, as shown in FIG. 1, the top surfaces of the first semiconductor sidewall 2012a, the first gate insulating sidewall 2013a, and the gate sidewall 2011a may be flush with the top surface of the second signal line 205, but it is not limited to this. In other embodiments, as shown in FIG. 4, the top of the first semiconductor sidewall 2012a has a first semiconductor overlapping portion 2012c that extends horizontally outward. The first semiconductor overlapping portion 2012c is formed on the top surface of the second signal line 205. The top of the first gate insulating sidewall 2013a has a first gate insulating overlapping portion 2013c that extends horizontally outward. The first gate insulating overlapping portion 2013c is formed on the top surface of the first semiconductor overlapping portion 2012c. The top of the gate sidewall 2011a has a gate overlapping portion 2011c that extends horizontally outward. The gate overlapping portion 2011c is formed on the top surface of the first gate insulating overlapping portion 2013c.

In some embodiments of the present disclosure, as shown in FIG. 1, in addition to the storage unit, the first signal line 204, and the second signal line 205, the storage layer 2 may also include a write bit line 207 and a write word line 208. The write bit line 207 may be formed on the side of the second signal line 205 away from the substrate 1. A second interlayer insulating layer 209 is formed between the layer where the write bit line 207 is located and the layer where the second signal line 205 is located. The write bit line 207 and the second interlayer insulating layer 209 horizontally surround the outer periphery of the extension portion of the second semiconductor layer 2022, and the write bit line 207 is in contact with the outer periphery of the first semiconductor layer 2012. The write word line 208 may be formed on the sides of the write bit line 207 and the extension portion of the second gate electrode 2021 away from the substrate 1. A third interlayer insulating layer 210 is formed between the layer where the write word line 208 is located and the layer where the write bit line 207 is located. The write word line 208 is connected to the top surface of the extension portion of the second gate electrode 2021.

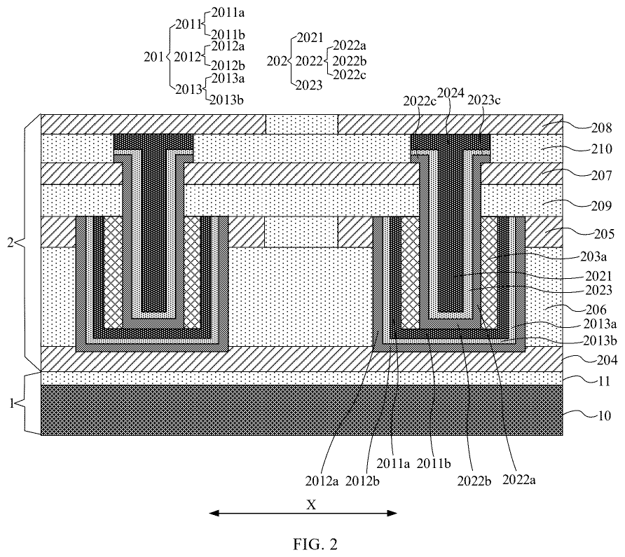

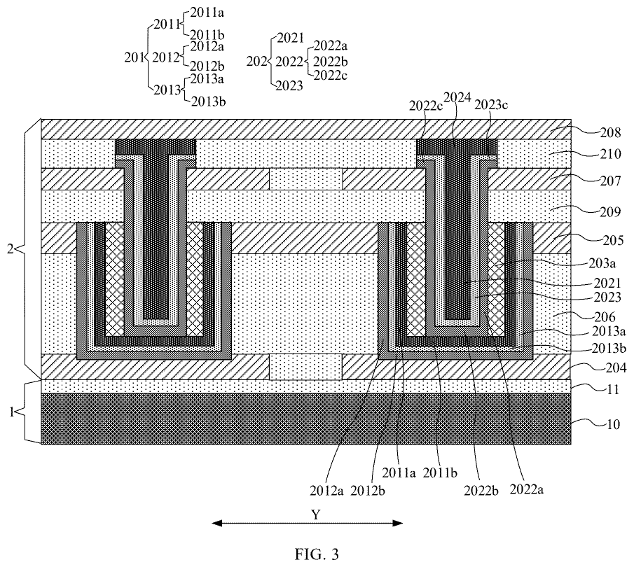

As shown in FIGS. 2 and 3, the write bit line 207 may extend in the first horizontal direction X, and the write word line 208 may extend in the second horizontal direction Y, such that the area of the overlapping region between the write bit line 207 and the second signal line 205 can be reduced, thereby reducing the parasitic capacitance therebetween, but it is not limited to this. The write bit line 207 may also extend in the second horizontal direction Y, and the write word line 208 may extend in the first horizontal direction X, depending on the specific situation.

For example, the write word line 208 and the write bit line 207 may be made of the same materials. For example, they can both be made of conductive materials such as tungsten metal, but it is not limited to this. They can also be made of other materials with conductive properties. In addition, the write word line 208 and the write bit line 207 can be signal lines made of a single material, but it is not limited to this, they can also be composite signal lines formed by stacking a plurality of materials, depending on the specific situation. The second interlayer insulating layer 209 and the third interlayer insulating layer 210 can be made of materials such as silicon dioxide, but it is not limited to this. They can also be made of other insulating materials, depending on the specific situation.

In some embodiments, as shown in FIGS. 1 and 4, the top of the extension portion of the second semiconductor layer 2022 has a second semiconductor overlapping portion 2022c that extends horizontally outward. The second semiconductor overlapping portion 2022c is formed on the top surface of the write bit line 207. The top of the extension portion of the second gate insulating layer 2023 has a second gate insulating overlapping portion 2023c that extends horizontally outward. The second gate insulating overlapping portion 2023c is formed on the top surface of the second semiconductor overlapping portion 2022c. The top surface of the extension portion of the second gate electrode 2021 is flush with the top surface of the second gate insulating overlapping portion 2023c, and the storage layer 2 also includes a conductive contact pad 2024. The bottom surface of the conductive contact pad 2024 is in contact with the top surface of the second gate insulating overlapping portion 2023c and the top surface of the extension portion of the second gate electrode 2021. The top surface of the conductive contact pad 2024 is in contact with the bottom surface of the write word line 208. This design can increase the contact area between the write transistor 202 and the write word line 208, thus ensuring the connection stability.

Exemplarily, the conductive contact pad 2024 in this embodiment can be integrally formed with the second gate electrode 2021 to reduce the process cost, but it is not limited to this. They can also be formed separately, depending on the specific situation.

In the embodiments of the present disclosure, as shown in FIGS. 2 and 3, the storage layer 2 may include a plurality of storage units. The plurality of storage units are arranged in an array in the first horizontal direction X and the second horizontal direction Y. The number of the first signal lines 204 is equal to the number of rows of the storage units in the array, and the number of the second signal lines 205 is equal to the number of rows of the storage unit in the array. The first signal lines 204 are arranged at intervals in the second horizontal direction Y. Each first signal line 204 is connected to the first semiconductor layer 2012 of the read transistor 201 in all the storage units in the corresponding row. The second signal lines 205 are arranged at intervals in the first horizontal direction X. Each second signal line 205 is connected to the first semiconductor layer 2012 of the read transistor 201 in all the storage units in the corresponding column.

As shown in FIGS. 2 and 3, if the write bit line 207 extends in the first horizontal direction X and the write word line 208 extends in the second horizontal direction Y, the number of the write bit lines 207 is equal to the number of rows of the storage units in the array, and the number of the write word lines 208 is equal to the number of columns of the storage units in the array. The write bit lines 207 are arranged at intervals in the second horizontal direction Y. Each write bit line 207 is connected to the second semiconductor layer 2022 of the write transistor 202 in all the storage units in the corresponding row. The write word lines 208 are arranged at intervals in the first horizontal direction X. Each write word line 208 is connected to the second gate electrode 2021 of the write transistor 202 in all the storage units in the corresponding column.

If the write bit line 207 extends in the second horizontal direction Y and the write word line 208 extends in the first horizontal direction X, the number of the write bit lines 207 is equal to the number of columns of the storage units in the array, and the number of the write word lines 208 is equal to the number of rows of the storage unit in the array. The write bit lines 207 are arranged at intervals in the first horizontal direction X. Each write bit line 207 is connected to the second semiconductor layer 2022 of the write transistor 202 in all the storage units in the corresponding column. The write word lines 208 are arranged at intervals in the second horizontal direction Y. Each write word line 208 is connected to the second gate electrode 2021 of the write transistor 202 in all the storage units in the corresponding row.

In this embodiment, the vertically nested storage units can reduce the horizontal area they occupy, such that the space occupied by the storage units can be reduced, thus more storage units can be arranged in each storage layer 2, thereby improving the storage density of the storage layer 2.

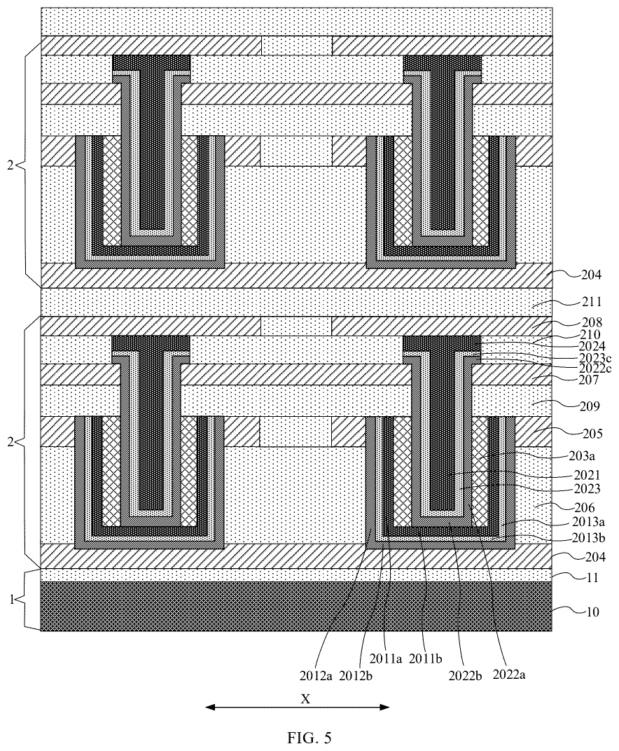

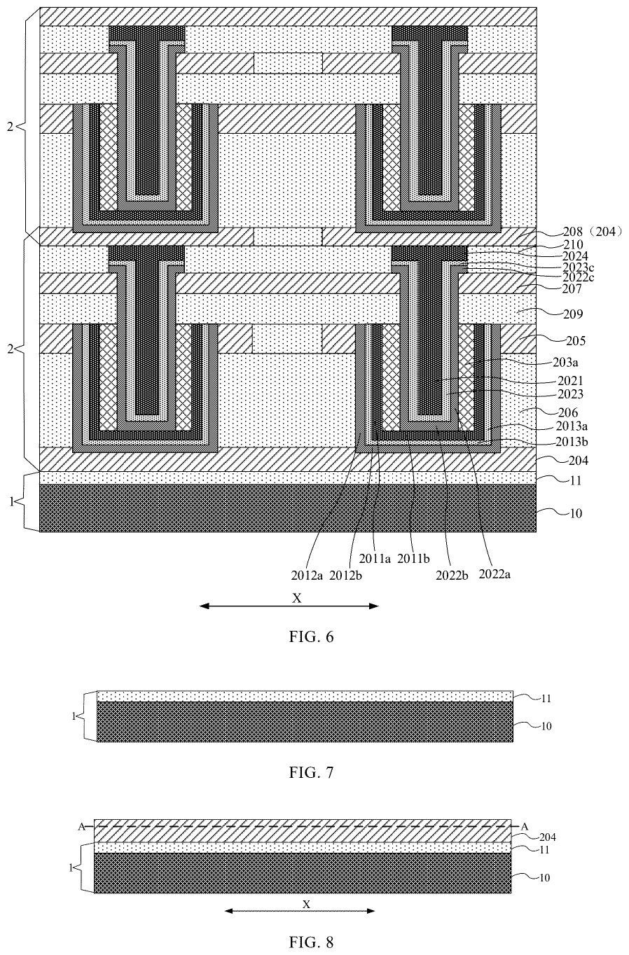

In the embodiments of the present disclosure, as shown in FIGS. 5 and 6, there are a plurality of the storage layers 2. The plurality of storage layers 2 can be stacked in the direction perpendicular to the substrate 1. In this embodiment, the vertically nested storage units can reduce the vertical height of the storage layer 2, such that when the height of the memory is fixed, more storage layers 2 can be arranged to improve the storage density of the memory.

In some embodiments, in two adjacent storage layers 2, the storage layer 2 closer to the substrate 1 is defined as a bottom storage layer, and the storage layer 2 farther from the substrate 1 is defined as a top storage layer. As shown in FIG. 5, in at least two adjacent storage layers 2, a fourth interlayer insulating layer 211 is formed between a layer where the first signal line 204 of the top storage layer is located and the layer where the write word line 208 of the bottom storage layer is located, such design allows more flexible control of each storage layer 2.

In other embodiments, as shown in FIG. 6, in at least two adjacent storage layers 2, the write word line 208 of the bottom storage layer can be shared as the first signal line 204 of the top storage layer, such design allows more storage layers 2 to be arranged within a fixed height, further improving the storage density of the memory.

The embodiments of the present disclosure also provide a method for manufacturing a memory, which is used to manufacture the memory described in any of the foregoing embodiments. The structure of the memory will not be repeated below, and the method for manufacturing the memory will be mainly described in detail.

In the embodiments of the present disclosure, the method for manufacturing the memory may include step S100 and step S102.

In step S100: providing a substrate 1 is provided. For example, an insulating substrate layer 11 can be formed on a semiconductor substrate layer 10 to form the substrate 1, as shown in FIG. 7.

In step S102: forming at least one storage layer 2 on the substrate 1. The steps of forming the storage layer 2 may at least include:

Step S1021: forming a read transistor 201 on the substrate 1. The read transistor 201 in this embodiment has a gate groove.

Step S1022: forming a write transistor 202 in the gate groove of the read transistor 201 to form a storage unit.

The manufacturing method of forming the storage layer on the substrate 1 in the present disclosure will be described in detail below with reference to FIGS. 1 to 24.

In some embodiments of the present disclosure, before step S1021, the steps of forming the storage layer 2 may also include step S10200, step S10201, step S10202, and step S10203.

In step S10200: forming a first signal line 204 on the substrate 1. The first signal line 204 extends in the first horizontal direction X, as shown in FIG. 8. For example, a first metal thin film covering the entire surface of the insulating substrate layer 11 can be deposited on the insulating substrate layer 11 of the substrate 1, and then the first metal thin film is patterned to form a plurality of first signal lines 204 arranged at intervals in the second horizontal direction Y, as shown in FIG. 9.

Continuing to shown in FIG. 9, a first insulating isolation pillar 212 can also be formed between adjacent first signal lines 204 to insulate adjacent first signal lines 204 from each other. The top surface of the first insulating isolation pillar 212 can be flush with the top surface of the first signal line. It should be noted that the first insulating isolation pillar 212 can be formed on the substrate 1 before the first signal line 204, or the first signal line 204 can be formed on the substrate 1 before the first insulating isolation pillar 212.

In step S10201: forming a first interlayer insulating layer 206 on the top surface of the first signal line 204. For example, after forming a plurality of first signal lines 204 arranged at intervals in the second horizontal direction Y, a first interlayer insulating layer 206 covering the entire surface of the first signal line 204 can be deposited. The first interlayer insulating layer 206 not only covers the top surface of the first signal line 204, but also covers the top surface of the first insulating isolation pillar 212. Then, a chemical mechanical polishing process can be used to polish the top surface of the first interlayer insulating layer 206 into a flat surface.

It should be noted that if the first insulating isolation pillar 212 is formed after the first signal line 204, the first interlayer insulating layer 206 can be integrally formed with the first insulating isolation pillar 212, but it is not limited to this. They can also be formed separately, that is, first the first insulating isolation pillar 212 is formed and then the first interlayer insulating layer 206 is formed.

In step S10202: forming a second signal line 205 on the top surface of the first interlayer insulating layer 206. The second signal line 205 extends in the second horizontal direction Y, and the orthographic projection of the second signal line 205 on the substrate 1 has a first overlapping region with the orthographic projection of the first signal line 204 on the substrate 1.

For example, the step S10202 may include the step S102021 and the step S102022. In step S102021: First, a second metal thin film 205a covering the entire surface of the first interlayer insulating layer 206 is deposited on the top surface of the first interlayer insulating layer 206, as shown in FIG. 10. In step S102022: patterning the second metal thin film 205a to form a plurality of second signal lines 205 arranged at intervals in the first horizontal direction X.

In step S10203: forming first accommodation hole 213. The orthographic projection of the first accommodation hole 213 on the substrate 1 is located within the first overlapping region. The first accommodation hole 213 penetrates through the second signal line 205 and the first interlayer insulating layer 206 and exposes the first signal line 204.

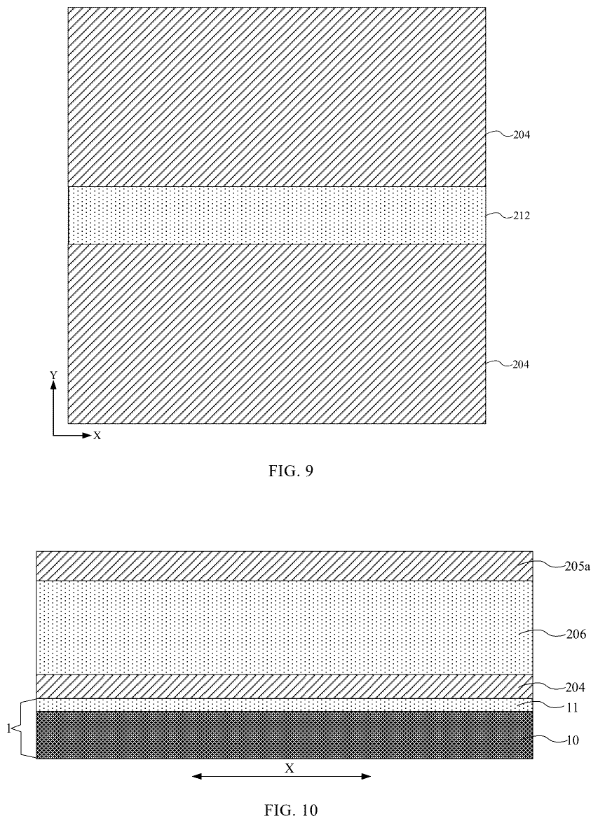

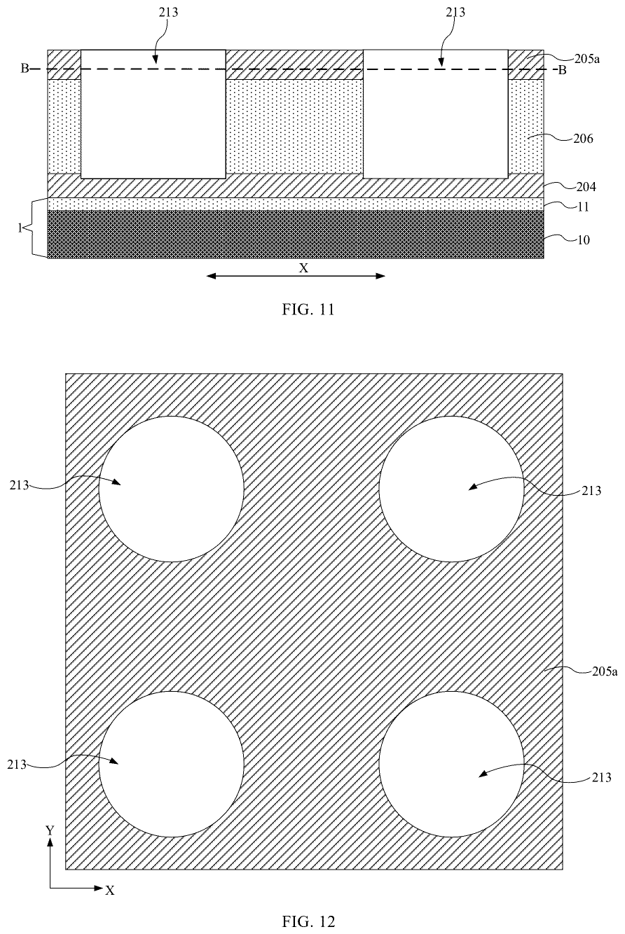

Referring to FIG. 11, the step S10203 can be executed after the step S102021 and before the step S102022. In this case, the statement that the first accommodation hole 213 in the step S10203 penetrates through the second signal line 205 can be understood as that the first accommodation hole 213 penetrates through the part of the second metal thin film 205a used to form the second signal line 205. It should be understood that the step S10203 can also be executed after the step S102022, depending on the specific situation.

For example, as shown in FIG. 11, the first accommodation hole 213 can extend into the interior of the first signal line 204, which can ensure the contact area between the subsequently formed read transistor 201 and the first signal line 204, but it is not limited to this. The first accommodation hole 213 can also just extend to the top surface of the first signal line 204, or the first accommodation hole 213 can penetrate through the first signal line 204, depending on the specific situation. In addition, there can be a plurality of first accommodation holes 213 in this embodiment, which are arranged in an array in the first horizontal direction X and the second horizontal direction Y, as shown in FIG. 12.

In some embodiments of the present disclosure, the step of forming the read transistor 201 includes: forming the first semiconductor layer 2012, the first gate insulating layer 2013, and the first gate electrode 2011 in the first accommodation hole 213. The first semiconductor layer 2012 at least horizontally surrounds the outer peripheral side of the first gate electrode 2011. The first gate insulating layer 2013 is formed between the first gate electrode 2011 and the first semiconductor layer 2012. The first gate electrode 2011 includes a gate bottom wall 2011b and a gate sidewall 2011a. The gate sidewall 2011a horizontally surrounds the gate bottom wall 2011b and extends in the direction away from the substrate 1. The gate sidewall 2011a and the gate bottom wall 2011b enclose to form a gate groove. The first signal line 204 can be in contact with the bottom surface of the first semiconductor layer 2012 and/or the bottom region of the outer peripheral surface of the first semiconductor layer 2012, and the second signal line 205 surrounds the outer peripheral side of the first semiconductor layer 2012 and is in contact with the top region of the outer peripheral surface of the first semiconductor layer 2012.

It should be noted that the step S102022 can be executed after the formation of the read transistor 201, but it is not limited to this and can also be executed before the formation of the read transistor 201, depending on the specific situation.

In detail, the steps of forming the first semiconductor layer 2012, the first gate insulating layer 2013, and the first gate electrode 2011 include step S10210, step S10211, step S10212, step S10213, and step S10214.

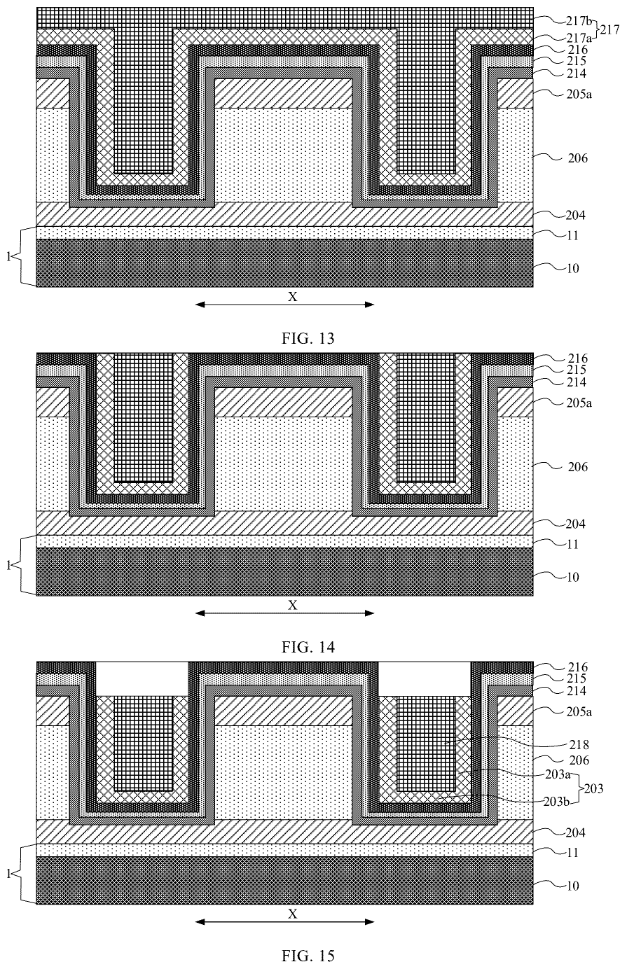

In step S10210: forming first semiconductor thin film 214 on the substrate 1. As shown in FIG. 13, the first semiconductor thin film 214 completely covers the top surface of the second signal line 205, the hole wall surface of the first accommodation hole 213, and the exposed surface of the first signal line 204 exposed by the first accommodation hole 213. For example, the first semiconductor thin film 214 can be deposited by an atomic layer deposition process, and the first semiconductor thin film 214 can be formed conformally to the shape of the underlying structural layer. It should be understood that the part of the first semiconductor thin film 214 located in the first accommodation hole 213 belongs to the aforementioned first semiconductor layer 2012.

It should be noted that if step S102022 is executed after the formation of the read transistor 201, the statement that the first semiconductor thin film 214 in step S10210 completely covers the top surface of the second signal line 205 can be understood as that the first semiconductor thin film 214 covers the second metal thin film 205a, as shown in FIG. 13.

In step S10211: forming a first gate insulating thin film 215 on the first semiconductor thin film 214. The first gate insulating thin film 215 completely covers the first semiconductor thin film 214, as shown in FIG. 13. For example, the first gate insulating thin film 215 can be deposited by an atomic layer deposition process, and the first gate insulating thin film 215 can be formed conformally to the shape of its underlying structural layer. It should be understood that the part of the first gate insulating thin film 215 located in the first accommodation hole 213 belongs to the aforementioned first gate insulating layer 2013.

In step S10212: forming a first conductive thin film 216 on the first gate insulating thin film 215. The first conductive thin film 216 completely covers the first gate insulating thin film 215, as shown in FIG. 13. For example, the first conductive thin film 216 can be deposited by an atomic layer deposition process, and the first conductive thin film 216 can be formed conformally to the shape of the underlying structural layer. It should be understood that the part of the first conductive thin film 216 located in the first accommodation hole 213 belongs to the first gate electrode 2011.

In step S10213: forming a filling film layer 217 on the first conductive thin film 216. The filling film layer 217 completely covers the first conductive thin film 216 and fills up the first accommodation hole 213. The filling film layer 217 can include an insulating dielectric thin film 217a and a sacrificial material thin film 217b formed on the insulating dielectric thin film 217a. The insulating dielectric thin film 217a completely covers the first conductive thin film 216.

The part of the insulating dielectric thin film 217a located at the gate groove belongs to the insulating dielectric portion 203. The insulating dielectric portion 203 can include an insulating dielectric sidewall 203a and an insulating dielectric bottom wall 203b. The insulating dielectric sidewall 203a horizontally surrounds the insulating dielectric bottom wall 203b and extends in a direction away from the substrate 1. The insulating dielectric sidewall 203a and the insulating dielectric bottom wall 203b enclose to form an insulating dielectric groove. The sacrificial material thin film 217b completely covers the insulating dielectric thin film 217a and fills up the first accommodation hole 213.

For example, after depositing the sacrificial material thin film 217b to completely cover the insulating dielectric thin film 217a and filling up the first accommodation hole 213, the chemical mechanical polishing process can be used to polish the sacrificial material thin film 217b, so that the top surface of the sacrificial material thin film 217b is a flat plane, which is beneficial to the accuracy of subsequent processes.

In some embodiments, the material of the insulating dielectric thin film 217a can be a low dielectric constant material, and the material of the sacrificial material thin film 217b can be a polysilicon material or a silicon dioxide material. It can also be understood that the insulating dielectric portion 203 can include a low dielectric constant material portion, and the sacrificial material portion can include a polysilicon material layer or a silicon dioxide material layer.

In step S10214: completely removing the parts of the filling film layer 217, the first conductive thin film 216, the first gate insulating thin film 215, and the first semiconductor thin film 214 located outside the target range of the first accommodation hole 213 to expose the second signal line 205, and forming simultaneously, the first semiconductor layer 2012, the first gate insulating layer 2013, and the first gate electrode 2011.

It should be noted that if the step S102022 is executed after the formation of the read transistor 201, the statement of exposing the second signal line 205 mentioned in step S10214 can be understood as exposing at least part of the second metal thin film 205a used to form the second signal line 205.

In some embodiments, the step of completely removing the parts of the filling film layer 217, the first conductive thin film 216, the first gate insulating thin film 215, and the first semiconductor thin film 214 located outside the target range of the first accommodation hole 213 can include: step S102140, step S102141, step S102142, step S102143, step S102144, and step S102145.

In step S102140: removing the part of the filling film layer 217 higher than the top surface of the first conductive thin film 216 to expose the top surface of the first conductive thin film 216, as shown in FIG. 14.

In step S102141: continuing to etch the part of the filling film layer 217 higher than the top surface of the second signal line 205, so that the top surface of the remaining filling portion of the filling film layer 217 is flush with the top surface of the second signal line 205, as shown in FIG. 15.

It should be noted that if the step S102022 is executed after the formation of the read transistor 201, the statement of making the top surface of the remaining filling portion of the filling film layer 217 flush with the top surface of the second signal line 205 mentioned in step S10214 can be understood as making the top surface of the remaining filling portion of the filling film layer 217 flush with the top surface of the second metal thin film 205a.

As shown in FIG. 15, the remaining filling portion can include an insulating dielectric portion 203 and a sacrificial material portion 218. The insulating dielectric portion 203 can be located at the gate groove of the first gate electrode 2011, and the sacrificial material portion 218 fills up the insulating dielectric groove of the insulating dielectric portion 203.

For example, when the material of the insulating dielectric thin film 217a in the filling film layer 217 is a low dielectric constant material and the material of the sacrificial material thin film 217b is a polysilicon material, in step S102140 and step S102141, Cl₂ (chlorine gas) and CHF₃ (trifluoromethane) can be used to etch the filling film layer 217. It should be understood that attention should be paid to the flatness of the remaining filling portion of the filling film layer 217 during the etching process.

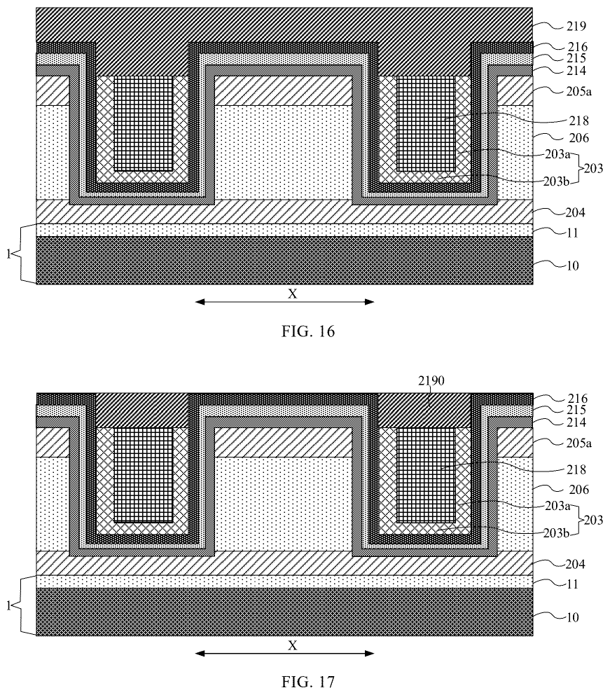

In step S102142: forming a protective film layer 219 on the top surface of the first conductive thin film 216 and the top surface of the remaining filling portion, as shown in FIG. 16. The protective film layer 219 is used to protect the remaining filling portion during subsequent etching processes. It should be understood that the top surface of the formed protective film layer 219 can be regarded as a horizontal plane, and this horizontal plane can be a plane parallel or approximately parallel to the substrate 1.

Under the same etching conditions, the etching rate of the protective film layer 219 is lower than the etching rates of the first conductive thin film 216, the first gate insulating thin film 215, and the first semiconductor thin film 214. For example, the protective film layer 219 in this embodiment can be a spin-on-carbon (SOC) coating, but it is not limited to this, as long as it can ensure that the etching rate of the protective film layer 219 is lower than the etching rates of the first conductive thin film 216, the first gate insulating thin film 215, and the first semiconductor thin film 214.

In step S102143: using a first etchant to etch off the part of the protective film layer 219 higher than the top surface of the first conductive thin film 216, so that the remaining protective portion 2190 of the protective film layer 219 remaining at the remaining filling portion is flush with the top surface of the first conductive thin film 216, as shown in FIG. 17. In the embodiments of the present disclosure, the first etchant can be an etching gas. For example, when the protective film layer 219 is a carbon coating, the first etchant can be a mixed gas of carbon tetrafluoride (CF₄) and oxygen (O₂).

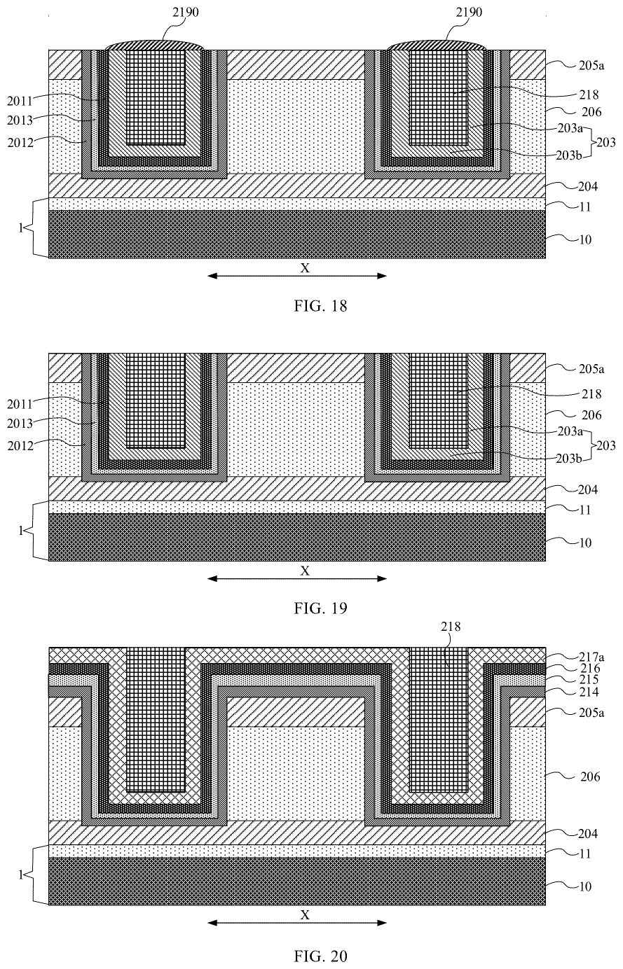

In step S102144: using a second etchant to completely remove the parts of the first conductive thin film 216, the first gate insulating thin film 215, and the first semiconductor thin film 214 higher than the top surface of the second signal line 205, to form the first semiconductor layer 2012, the first gate insulating layer 2013, and the first gate electrode 2011. And the remaining protective portion 2190 is etched off by a certain height under the action of the second etchant, and a part of the remaining protective portion 2190 still covers the remaining filling portion, as shown in FIG. 18.

In the embodiments of the present disclosure, the second etchant can be an etching gas. For example, the second etchant can be a mixed gas containing fluorine, chlorine, and oxygen. For example, the second etchant can be a mixed gas of CF₄, Cl₂ (chlorine gas), and O₂. which has a relatively low etching selectivity for the materials of the first conductive thin film, the first gate insulating thin film, and the first semiconductor thin film, thus the etching uniformity can be improved to make the top surfaces of the first semiconductor layer 2012, the first gate insulating layer 2013, and the first gate electrode 2011 flush.

In step S102145: using a third etchant to completely remove the part of the remaining protective portion 2190 remaining on the remaining filling portion, as shown in FIG. 19. The top surfaces of the first semiconductor layer 2012, the first gate insulating layer 2013, the first gate electrode 2011, and the remaining filling portion are flush with the top surface of the second signal line 205. The outside of the target range is the position outside the first accommodation hole 213.

It should be noted that if step S102022 is executed after the formation of the read transistor 201, the statement that the top surfaces of the first semiconductor layer 2012, the first gate insulating layer 2013, the first gate electrode 2011, and the remaining filling portion are flush with the top surface of the second signal line 205 mentioned in step S10215 can be understood as that the top surfaces of the first semiconductor layer 2012, the first gate insulating layer 2013, the first gate electrode 2011, and the remaining filling portion are flush with the top surface of the second metal thin film 205a.

In the embodiments of the present disclosure, methods such as ashing or wet cleaning can be used to completely remove the part of the remaining protective portion 2190 remaining on the filling film layer 217. When the ashing method is used, the third etchant can be an asher gas. For example, the asher gas can include oxygen.

It should be noted that if the material of the insulating dielectric portion 203 is a low dielectric constant material, in step S102145, attention should be paid to the ratio of the asher gas to reduce the oxidation of the low dielectric constant material, thereby reducing the occurrence of defects in the formation of the insulating dielectric portion 203.

In some other embodiments, the step of completely removing the parts of the filling film layer 217, the first conductive thin film 216, the first gate insulating thin film 215, and the first semiconductor thin film 214 located outside the target range of the first accommodation hole 213 can include: step S102146 and step S102147.

In step S102146: removing the part of the sacrificial material thin film 217b higher than the top surface of the insulating dielectric thin film 217a to expose the top surface of the insulating dielectric thin film 217a. The part of the sacrificial material thin film 217b remaining in the insulating dielectric groove is the sacrificial material portion 218, and the top surface of the sacrificial material portion 218 is flush with the top surface of the insulating dielectric thin film 217a, as shown in FIG. 20.

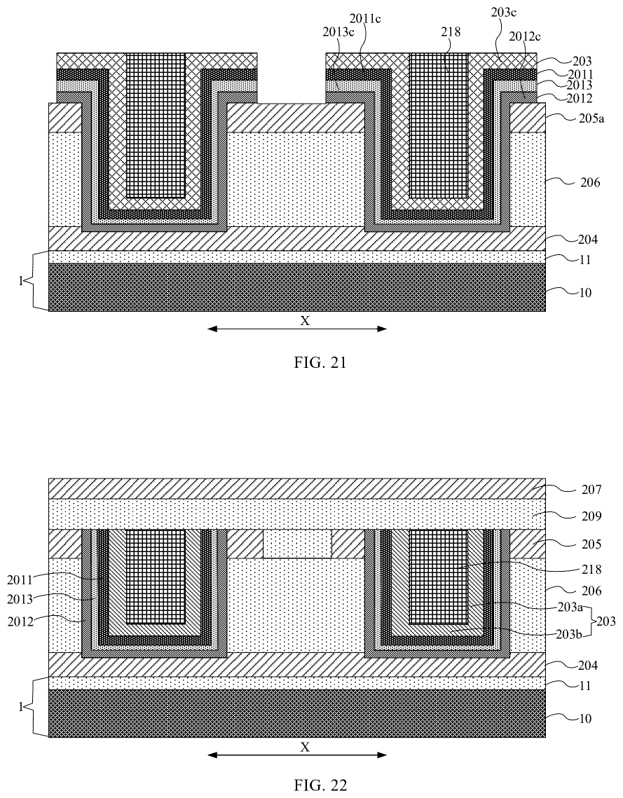

In step S102147: etching off the parts of the insulating dielectric thin film 217a, the first conductive thin film 216, the first gate insulating thin film 215, and the first semiconductor thin film 214 that are located outside the target range of the first accommodation hole 213 to form the insulating dielectric portion 203, the first semiconductor layer 2012, the first gate insulating layer 2013, and the first gate electrode 2011, as shown in FIG. 21. The region outside the target range is the region where the distance from the hole boundary of the first accommodation hole 213 exceeds the target value, and the target value is greater than 0, to make the top of the first semiconductor layer 2012 form a first semiconductor overlapping portion 2012c that extends horizontally outward. The first semiconductor overlapping portion 2012c is formed on the top surface of the second signal line 205. The top of the first gate insulating layer 2013 has a first gate insulating overlapping portion 2013c that extends horizontally outward. The first gate insulating overlapping portion 2013c is formed on the top surface of the first semiconductor overlapping portion 2012c. The top of the gate sidewall 2011a has a gate overlapping portion 2011c that extends horizontally outward. The gate overlapping portion 2011c is formed on the top surface of the first gate insulating overlapping portion 2013c. The top of the insulating dielectric sidewall 203a has an insulating dielectric overlapping portion 203c that extends horizontally outward. The insulating dielectric overlapping portion 203c is formed on the top surface of the gate overlapping portion 2011c.

It should be noted that if the step S102022 is executed after the formation of the read transistor 201, the statement that the first semiconductor overlapping portion 2012c mentioned in step S10214 is formed on the top surface of the second signal line 205 can be understood as that the first semiconductor overlapping portion 2012c is formed on the top surface of the second metal thin film 205a.

For example, in step S102147, a photolithography process can be used to etch away the parts of the insulating dielectric thin film 217a, the first conductive thin film 216, the first gate insulating thin film 215, and the first semiconductor thin film 214 that are located outside the target range of the first accommodation hole 213, so as to form the insulating dielectric portion 203, the first semiconductor layer 2012, the first gate insulating layer 2013, and the first gate electrode 2011. Specifically, after step S102146, a Bottom Anti-Reflection Coating (BARC) material layer and a photoresist layer that cover the entire surface can be formed in sequence. Then, a photomask is used to pattern the BARC material layer and the photoresist layer, so that the BARC material layer and the photoresist layer form a mask structure with a target pattern. Then, this mask structure is used to perform an etching process to etch away the parts of the insulating dielectric thin film 217a, the first conductive thin film 216, the first gate insulating thin film 215, and the first semiconductor thin film 214 that are located outside the target range of the first accommodation hole 213, thereby forming the insulating dielectric portion 203, the first semiconductor layer 2012, the first gate insulating layer 2013, and the first gate electrode 2011.

The Bottom Anti-Reflection Coating (BARC) material layer is mainly used to reduce the amount of light reflected back to the photoresist layer during the exposure process, so as to reduce the standing wave effect and help improve the accuracy of the photolithography process. The BARC material layer can be formed by spin coating, and its main components include crosslinkable resins, thermal acid generators, surfactants, and solvents to reduce the interference of light.

It should be understood that after the formation of the insulating dielectric portion 203, the first semiconductor layer 2012, the first gate insulating layer 2013, and the first gate electrode 2011, the mask structure formed by the BARC material layer and the photoresist layer can be removed.

For example, step S102022 of this embodiment can be executed after step S102147.

In some embodiments of the present disclosure, the steps of forming the write transistor 202 may include step S10220, step S10221, step S10222, and step S10223.

In step S10220: forming a second interlayer insulating layer 209 on the top surfaces of the read transistor 201, the insulating dielectric portion 203, and the sacrificial material portion 218. It should be understood that the second interlayer insulating layer 209 can cover the structural layers below it as a whole, and the top surface of the second interlayer insulating layer 209 can be a plane parallel or approximately parallel to the substrate 1 to ensure the flatness of the subsequent film layers to be formed.

In step S10221: forming a write bit line 207 on the side of the second interlayer insulating layer 209 away from the substrate 1. The orthographic projection of the write bit line 207 on the substrate 1 completely covers the orthographic projection of the sacrificial material portion 218 on the substrate 1, as shown in FIG. 22. For example, a third metal thin film that covers the entire surface of the second interlayer insulating layer 209 can be deposited on the top surface of the second interlayer insulating layer 209, and then the third metal thin film is patterned to form a plurality of write bit lines 207 arranged at intervals in the second horizontal direction Y (or the first horizontal direction X). A second insulating isolation pillar can also be arranged between adjacent write bit lines 207, and the top surface of the second insulating isolation pillar can be flush with the top surface of the write bit line 207 to ensure the flatness of the subsequent film layers to be formed.

In this embodiment, the second insulating isolation pillar can be formed before the write bit line 207, or the write bit line 207 can be formed before the second insulating isolation pillar, depending on the specific situation.

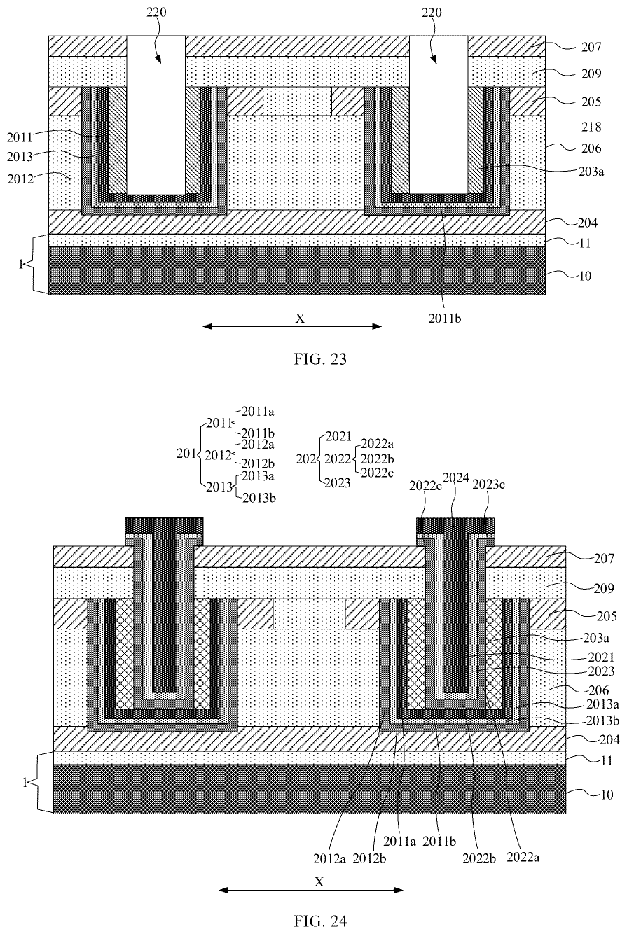

In step S10222: completely etching off the sacrificial material portion 218 and the insulating dielectric bottom wall 203b of the insulating dielectric portion 203, and completely etching off the parts of the second interlayer insulating layer 209 and the write bit line 207 located on the sacrificial material portion 218 to form a second accommodation hole 220. The second accommodation hole 220 exposes part of the gate bottom wall 2011b. The insulating dielectric sidewall 203a of the insulating dielectric portion 203 is retained. For example, the second accommodation hole 220 can just extend into the interior of the gate bottom wall 2011b, which can ensure the area of the subsequently formed storage node, thereby ensuring the storage capacitance, but it is not limited to this. As shown in FIG. 23, the second accommodation hole 220 can also just extend to the top surface of the gate bottom wall 2011b, or the second accommodation hole 220 can penetrate through the gate bottom wall 2011b, depending on the specific situation. In addition, it should be understood that there can be a plurality of second accommodation holes 220 in this embodiment, which are arranged in an array in the first horizontal direction X and the second horizontal direction Y.

In step S10223: forming a second semiconductor layer 2022, a second gate insulating layer 2023, and a second gate electrode 2021 in the second accommodation hole 220, as shown in FIG. 24. For example, the manufacturing methods of the second semiconductor layer 2022, the second gate insulating layer 2023, and the second gate electrode 2021 can refer to those of the first semiconductor layer 2012, the second gate insulating layer 2023, and the second gate electrode 2021 respectively, and will not be elaborated here.

It should be noted that after the formation of the write transistor 202, the steps of forming the storage layer 2 may also include forming a third interlayer insulating layer 210 and a write word line 208 in sequence, as shown in FIG. 3, and will not be elaborated here.

If, as shown in FIG. 5, in two adjacent storage layers 2, the first signal line 204 of the top-layer storage layer is not shared with the write word line 208 of the bottom storage layer, then the fourth interlayer insulating layer 211 shown in FIG. 5 can be formed first before forming the first signal line 204 of the top storage layer, and will not be elaborated here. If, as shown in FIG. 6, in two adjacent storage layers 2, the first signal line 204 of the top storage layer is shared with the write word line 208 of the bottom storage layer, then the fabrication of one insulating layer and one signal line can be omitted, that is, the steps of fabricating the fourth interlayer insulating layer 211 and the first signal line 204 in the top storage layer can be omitted to reduce the manufacturing cost and improve the storage density.

In addition, terms such as “first”, “second”, “third”, and “fourth” are only used for descriptive purposes and should not be construed as indicating or implying relative importance or implicitly specifying the quantity of the indicated technical features. Thus, the features defined with “first”, “second”, “third”, and “fourth” may explicitly or implicitly include one or more of such features. In the description of this application, “a plurality of” means two or more, unless otherwise specifically defined.

In the description of this specification, descriptions referring to terms such as “some embodiments” and “exemplarily” mean that the specific features, structures, materials, or characteristics described in conjunction with the embodiments or examples are included in at least one embodiment or example of this application. In this specification, the schematic representations of the above terms are not necessarily directed to the same embodiment or example. Moreover, the described specific features, structures, materials, or characteristics can be combined in a suitable manner in any one or more embodiments or examples. In addition, those skilled in the art can combine the different embodiments or examples and the features of different embodiments or examples described in this specification without conflicting with each other.

Although the embodiments of the present application have been shown and described above, it can be understood that the above embodiments are exemplary and should not be construed as limiting the present application. Those skilled in the art can make changes, modifications, substitutions, and variations to the above embodiments within the scope of the present application. Therefore, any changes or modifications made according to the claims and the specification of the present application should fall within the scope covered by the patent of the present application.

What is claimed is:

1. A memory device, comprising a substrate and at least one storage layer formed on the substrate, wherein each storage layer comprises a storage unit, and the storage unit comprises:
a read transistor, comprising a first gate electrode, a first semiconductor layer at least horizontally surrounding an outer peripheral side of the first gate electrode, and a first gate insulating layer formed between the first gate electrode and the first semiconductor layer, wherein the first gate electrode comprises a gate bottom wall and a gate sidewall, and the gate sidewall horizontally surrounds the gate bottom wall and extends in a direction away from the substrate, and the gate sidewall and the gate bottom wall enclose to form a gate groove; and
a write transistor, comprising a second gate electrode, a second semiconductor layer at least horizontally surrounding an outer peripheral side of the second gate electrode, and a second gate insulating layer formed between the second gate electrode and the second semiconductor layer;
wherein a part of the second semiconductor layer is embedded in the gate groove and is in contact with at least a part of the gate groove.

2. The memory device according to claim 1, wherein each of the second semiconductor layer, the second gate electrode, and the second gate insulating layer has an embedding portion that is embedded in the gate groove and an extension portion located on a side of the embedding portion away from the substrate, wherein the extension portion protrudes in the direction away from the substrate relative to the read transistor.

3. The memory device according to claim 2, wherein the storage unit further comprises an insulating dielectric sidewall embedded in the gate groove and horizontally surrounding an outer peripheral side of the embedding portion of the second semiconductor layer;
wherein an outer peripheral surface of the embedding portion of the second semiconductor layer is insulated from the gate sidewall by the insulating dielectric sidewall, and a bottom surface of the embedding portion of the second semiconductor layer is in contact with the gate bottom wall.

4. The memory device according to claim 3, wherein the insulating dielectric sidewall comprises at least one of a low dielectric material portion and a silicon dioxide material layer, and at least one of the low dielectric material portion and the silicon dioxide material layer horizontally surrounds the outer peripheral side of the embedding portion of the second semiconductor layer.

5. The memory device according to claim 3, wherein the embedding portion of the second semiconductor layer comprises a second semiconductor sidewall and a second semiconductor bottom wall, and the second semiconductor sidewall horizontally surrounds the second semiconductor bottom wall and extends in the direction away from the substrate;
wherein the second semiconductor sidewall and the second semiconductor bottom wall enclose to form a second semiconductor groove, and the embedding portion of the second gate electrode and the embedding portion of the second gate insulating layer are located within the second semiconductor groove;
wherein a bottom surface of the second semiconductor bottom wall and a bottom surface of the second semiconductor sidewall are each in contact with a bottom surface of the gate groove.

6. The memory device according to claim 1, wherein each storage layer further comprises:
a first signal line formed on the substrate, wherein the first signal line extends in a first horizontal direction and is in contact with at least one of a bottom surface of the first semiconductor layer and a bottom region of an outer peripheral surface of the first semiconductor layer;
a second signal line formed on a side of the first signal line away from the substrate,
wherein a first interlayer insulating layer is formed between a layer where the second signal line is located and a layer where the first signal line is located, wherein the second signal line extends in a second horizontal direction intersecting with the first horizontal direction, the second signal line and the first interlayer insulating layer horizontally surround the outer peripheral side of the first semiconductor layer, and the second signal line is in contact with a top region of the outer peripheral surface of the first semiconductor layer;
wherein one of the first signal line and the second signal line is a read bit line, and another one of the first signal line and the second signal line is a read word line.

7. The memory device according to claim 6, wherein the first semiconductor layer is formed on the side of the first signal line away from the substrate, wherein the first semiconductor layer comprises a first semiconductor sidewall and a first semiconductor bottom wall;
wherein the first semiconductor sidewall horizontally surrounds the first semiconductor bottom wall and extends in the direction away from the substrate, and the first semiconductor sidewall and the first semiconductor bottom wall enclose to form a first semiconductor groove;
wherein the first gate insulating layer comprises a first gate insulating sidewall and a first gate insulating bottom wall, the first gate insulating bottom wall is located within the first semiconductor groove and is in contact with a top surface of the first semiconductor bottom wall, and the first gate insulating sidewall is at least located within the first semiconductor groove and horizontally surrounds the first gate insulating bottom wall;
wherein the first gate insulating sidewall extends in the direction away from the substrate and forms a first gate insulating groove with the first gate insulating bottom wall, and an outer peripheral surface of the first gate insulating sidewall is in contact with an inner peripheral surface of the first semiconductor sidewall; and
wherein the gate bottom wall is located within the first gate insulating groove and is in contact with a top surface of the first gate insulating bottom wall, and wherein the gate sidewall is at least located within the first gate insulating groove, and an outer peripheral surface of the gate sidewall is in contact with an inner peripheral surface of the first gate insulating sidewall.

8. The memory device according to claim 7, wherein the top surface of the first semiconductor sidewall, a top surface of the first gate insulating sidewall, and a top surface of the gate sidewall are flush with a top surface of the second signal line; or
a top of the first semiconductor sidewall is provided with a first semiconductor overlapping portion extending horizontally outward, the first semiconductor overlapping portion is formed on the top surface of the second signal line, a top of the first gate insulating sidewall is provided with a first gate insulating overlapping portion extending horizontally outward, the first gate insulating overlapping portion is formed on a top surface of the first semiconductor overlapping portion, and a top of the gate sidewall is provided with a gate overlapping portion extending horizontally outward, and the gate overlapping portion is formed on a top surface of the first gate insulating overlapping portion.

9. The memory device according to claim 6, wherein each storage layer further comprises:
a write bit line formed on a side of the second signal line away from the substrate,
wherein a second interlayer insulating layer is formed between a layer where the write bit line is located and a layer where the second signal line is located, the write bit line and the second interlayer insulating layer horizontally surround an outer peripheral side of an extension portion of the second semiconductor layer, and the write bit line is in contact with the outer peripheral surface of the second semiconductor layer; and
a write word line formed on a side of an extension portion of the second gate electrode away from the substrate, wherein a third interlayer insulating layer is formed between a layer where the write word line is located and a layer where the write bit line is located, and the write word line is connected to a top surface of the extension portion of the second gate electrode;
wherein one of the write bit line and the write word line extends in the first horizontal direction, and another one of the write bit line and the write word line extends in the second horizontal direction.

10. The memory device according to claim 9, wherein a top of the extension portion of the second semiconductor layer is provided with a second semiconductor overlapping portion extending horizontally outward, the second semiconductor overlapping portion is formed on the top surface of the write bit line, a top of the extension portion of the second gate insulating layer is provided with a second gate insulating overlapping portion extending horizontally outward;
wherein the second gate insulating overlapping portion is formed on the top surface of the second semiconductor overlapping portion, a top surface of the extension portion of the second gate electrode is flush with the top surface of the second gate insulating overlapping portion, and
wherein each storage layer further comprises a conductive contact pad, a bottom surface of the conductive contact pad is in contact with the top surface of the second gate insulating overlapping portion and the top surface of the extension portion of the second gate electrode, and a top surface of the conductive contact pad is in contact with the bottom surface of the write word line.

11. The memory device according to claim 9, wherein a plurality of storage layers are stacked in a direction perpendicular to the substrate, wherein the storage layer close to the substrate among at least two adjacent storage layers is defined as a bottom storage layer, and the storage layer away from the substrate is defined as a top storage layer;
wherein among at least two adjacent storage layers: a fourth interlayer insulating layer is formed between a layer where the first signal line of the top storage layer is located and a layer where the write word line of the bottom storage layer is located; or
among at least two adjacent storage layers: the write word line of the bottom storage layer is shared as the first signal line of the top storage layer.

12. A method for manufacturing a memory, comprising:
providing a substrate; and
forming at least one storage layer on the substrate,
wherein forming the at least one storage layer comprises:
forming a read transistor on the substrate, wherein the read transistor comprises a first gate electrode, a first semiconductor layer at least horizontally surrounding an outer peripheral side of the first gate electrode, and a first gate insulating layer formed between the first gate electrode and the first semiconductor layer, wherein the first gate electrode comprises a gate bottom wall and a gate sidewall, and wherein the gate sidewall horizontally surrounds the gate bottom wall and extends in a direction away from the substrate, and the gate sidewall and the gate bottom wall enclose to form a gate groove; and
forming a write transistor at the gate groove to form a storage unit, wherein the write transistor comprises a second gate electrode, a second semiconductor layer at least horizontally surrounding an outer peripheral side of the second gate electrode, and a second gate insulating layer formed between the second gate electrode and the second semiconductor layer; and wherein a part of the second semiconductor layer is embedded at the gate groove and is in contact with at least part of the gate groove.

13. The method according to claim 12, wherein before forming the read transistor, forming the at least one storage layer further comprises:
forming a first signal line on the substrate, wherein the first signal line extends in a first horizontal direction;
forming a first interlayer insulating layer on a top surface of the first signal line;
forming a second signal line on a top surface of the first interlayer insulating layer, wherein the second signal line extends in a second horizontal direction, and an orthographic projection of the second signal line on the substrate has a first overlapping region with an orthographic projection of the first signal line on the substrate; and
forming a first accommodation hole, wherein an orthographic projection of the first accommodation hole on the substrate is located within the first overlapping region, and the first accommodation hole penetrates through the second signal line and the first interlayer insulating layer and exposes the first signal line.

14. The method according to claim 13, wherein forming the read transistor comprises:
forming the first semiconductor layer, the first gate insulating layer and the first gate electrode in the first accommodation hole, wherein the first semiconductor layer at least horizontally surrounds an outer peripheral side of the first gate electrode, the first gate insulating layer is formed between the first gate electrode and the first semiconductor layer;
wherein the first gate electrode comprises a gate bottom wall and a gate sidewall, wherein the gate sidewall horizontally surrounds the gate bottom wall and extends in the direction away from the substrate, and the gate sidewall and the gate bottom wall enclose a gate groove;
wherein the first signal line is in contact with at least one of a bottom surface of the first semiconductor layer and a bottom region of an outer peripheral surface of the first semiconductor layer, and the second signal line surrounds an outer peripheral side of the first semiconductor layer and is in contact with a top region of the outer peripheral surface of the first semiconductor layer.

15. The method according to claim 14, wherein forming the first semiconductor layer, the first gate insulating layer and the first gate electrode comprises:
forming a first semiconductor thin film on the substrate, wherein the first semiconductor thin film completely covers a top surface of the second signal line, a hole wall surface of the first accommodation hole and an exposed surface of the first signal line exposed by the first accommodation hole, and a part of the first semiconductor thin film located in the first accommodation hole belongs to the first semiconductor layer;
forming a first gate insulating thin film on the first semiconductor thin film, wherein the first gate insulating thin film completely covers the first semiconductor thin film, and a part of the first gate insulating thin film located in the first accommodation hole belongs to the first gate insulating layer;
forming a first conductive thin film on the first gate insulating thin film, wherein the first conductive thin film completely covers the first gate insulating thin film, and a part of the first conductive thin film located in the first accommodation hole belongs to the first gate electrode;
forming a filling film layer on the first conductive thin film, wherein the filling film layer completely covers the first conductive thin film and fills up the first accommodation hole; and
completely removing parts of the filling film layer, the first conductive thin film, the first gate insulating thin film and the first semiconductor thin film located outside a target range of the first accommodation hole to expose the second signal line, and simultaneously forming the first semiconductor layer, the first gate insulating layer and the first gate electrode.

16. The method according to claim 15, wherein completely removing the parts of the filling film layer, the first conductive thin film, the first gate insulating thin film and the first semiconductor thin film located outside the target range of the first accommodation hole comprises:
removing a part of the filling film layer higher than a top surface of the first conductive thin film to expose the top surface of the first conductive thin film;
etching a part of the filling film layer higher than a top surface of the second signal line to make a top surface of a remaining filling portion of the filling film layer flush with the top surface of the second signal line;
forming a protective film layer on the top surface of the first conductive thin film and the top surface of the remaining filling portion, wherein a top surface of the protective film layer is a horizontal plane, and under the same etching condition, an etching rate of the protective film layer is less than etching rates of the first conductive thin film, the first gate insulating thin film and the first semiconductor thin film;
using a first etchant to etch off the part of the protective film layer higher than the top surface of the first conductive thin film to make a remaining protective portion of the protective film layer remaining at the remaining filling portion flush with a top surface of the first conductive thin film;
using a second etchant to completely remove the parts of the first conductive thin film, the first gate insulating thin film and the first semiconductor thin film higher than the top surface of the second signal line to form the first semiconductor layer, the first gate insulating layer and the first gate electrode, the remaining protective portion is etched off by a certain height under an action of the second etchant, and a part of the remaining protective portion still covers the remaining filling portion; and
using a third etchant to completely remove the part of the remaining protective portion remaining on the remaining filling portion;
wherein the top surfaces of the first semiconductor layer, the first gate insulating layer, the first gate electrode and the remaining filling portion are flush with the top surface of the second signal line, and an outside of the target range is a position outside the first accommodation hole.

17. The method according to claim 16, wherein the remaining filling portion comprises:
an insulating dielectric portion located at the gate groove of the first gate electrode, wherein the insulating dielectric portion comprises an insulating dielectric bottom wall and an insulating dielectric sidewall, and the insulating dielectric sidewall horizontally surrounds the insulating dielectric bottom wall and extends in the direction away from the substrate, and the insulating dielectric sidewall and the insulating dielectric bottom wall enclose to form an insulating dielectric groove; and
a sacrificial material portion, filling up the insulating dielectric groove.

18. The method according to claim 15, wherein the filling film layer comprises:
an insulating dielectric thin film and a sacrificial material thin film formed on the insulating dielectric thin film;
wherein the insulating dielectric thin film completely covers the first conductive thin film, and a part of the insulating dielectric thin film located at the gate groove belongs to an insulating dielectric portion;
wherein the insulating dielectric portion comprises an insulating dielectric bottom wall and an insulating dielectric sidewall, wherein the insulating dielectric sidewall horizontally surrounds the insulating dielectric bottom wall and extends in the direction away from the substrate;
wherein the insulating dielectric sidewall and the insulating dielectric bottom wall enclose to form an insulating dielectric groove, and the sacrificial material thin film completely covers the insulating dielectric thin film and fills up the first accommodation hole;
wherein completely removing the parts of the filling film layer, the first conductive thin film, the first gate insulating thin film and the first semiconductor thin film located outside the target range of the first accommodation hole comprises:
etching off a part of the sacrificial material thin film higher than a top surface of the insulating dielectric thin film to expose the top surface of the insulating dielectric thin film, wherein the part of the sacrificial material thin film remaining in the insulating dielectric groove is a sacrificial material portion, and the top surface of the sacrificial material portion is flush with the top surface of the insulating dielectric thin film;
etching off the parts of the insulating dielectric thin film, the first conductive thin film, the first gate insulating thin film and the first semiconductor thin film located outside the target range of the first accommodation hole to form the insulating dielectric portion, the first semiconductor layer, the first gate insulating layer and the first gate electrode;
wherein outside of the target range is a region where a distance from a hole boundary of the first accommodation hole exceeds a target value, and the target value is greater than 0, so that a first semiconductor overlapping portion extending horizontally outward is formed at the top of the first semiconductor layer, and the first semiconductor overlapping portion is formed on the top surface of the second signal line;
wherein a first gate insulating overlapping portion extending horizontally outward is formed at a top of the first gate insulating layer, and the first gate insulating overlapping portion is formed on the top surface of the first semiconductor overlapping portion;
wherein a gate overlapping portion extending horizontally outward is formed at the top of the gate sidewall, and the gate overlapping portion is formed on the top surface of the first gate insulating overlapping portion;
wherein an insulating dielectric overlapping portion extending horizontally outward is formed at the top of the insulating dielectric sidewall; and the insulating dielectric overlapping portion is formed on the top surface of the gate overlapping portion.

19. The method according to claim 17, wherein the insulating dielectric sidewall comprises a low dielectric material portion, and the sacrificial material portion comprises a polysilicon material layer or a silicon dioxide material layer.

20. The method according to claim 17, wherein forming the write transistor comprises:
forming a second interlayer insulating layer on the top surfaces of the read transistor, the insulating dielectric portion and the sacrificial material portion;
forming a write bit line on a side of the second interlayer insulating layer away from the substrate; wherein an orthographic projection of the write bit line on the substrate completely covers an orthographic projection of the sacrificial material portion on the substrate;
completely etching the sacrificial material portion and the insulating dielectric bottom wall, and completely etching off the parts of the second interlayer insulating layer and the write bit line located on the sacrificial material portion to form a second accommodation hole, wherein the second accommodation hole exposes a part of the gate bottom wall; and
forming the second semiconductor layer, the second gate insulating layer and the second gate electrode in the second accommodation hole.
